(19) United States
(12) Patent Application Publication
(10) Pub. No.: US 2025/0310628 A1
(43) Pub. Date: Oct. 2, 2025

(54) DETECTION DEVICE

(71) Applicant: Japan Display Inc., Tokyo (JP)

(72) Inventors: Keiichi SAITO, Tokyo (JP); Atsunori OYAMA, Tokyo (JP); Gen KOIDE, Tokyo (JP)

(21) Appl. No.: 19/240,831

(22) Filed: Jun. 17, 2025

Related U.S. Application Data
(63) Continuation of application No. PCT/JP2023/045052, filed on Dec. 15, 2023.

(30) Foreign Application Priority Data
Dec. 20, 2022 (JP) 2022-203691

(51) Int. Cl. H04N 23/56; H10K 39/00

(52) U.S. Cl. CPC H04N 23/56; H10K 39/601

(57) ABSTRACT

According to an aspect, a detection device includes: a substrate; a plurality of photodiodes in each of which a lower electrode, a lower buffer layer, an active layer, an upper buffer layer, and an upper electrode are stacked on the substrate in the order as listed; an insulating film provided between a plurality of the lower electrodes adjacent to each other; and a light-blocking layer provided in an area overlapping the insulating film in plan view. The lower electrodes of the photodiodes are arranged separated from each other so as to correspond to the photodiodes. The lower buffer layer, the active layer, the upper buffer layer, and the upper electrode are provided continuously across the photodiodes so as to cover the lower electrodes and the insulating film.

### CROSS-REFERENCE TO RELATED APPLICATION

This application claims the benefit of priority from Japanese Patent Application No. 2022-203691 filed on Dec. 20, 2022 and International Patent Application No. PCT/JP2023/045052 filed on Dec. 15, 2023, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vascular patterns are known (for example, Japanese Patent Application Laid-open Publication No. 2009-032005). Such optical sensors each include a plurality of photodiodes (organic photodiodes (OPDs)) each using an organic semiconductor material as an active layer. As described in International Patent Application Publication No. WO 2020/188959, in each of the photodiodes, for example, a lower electrode, an electron transport layer, the active layer, a hole transport layer, and an upper electrode are stacked in this order. The electron transport layer and the hole transport layer are each also called a buffer layer.

Optical sensors that include such OPDs are required to have higher detection accuracy.

### SUMMARY

According to an aspect, a detection device includes: a substrate; a plurality of photodiodes in each of which a lower electrode, a lower buffer layer, an active layer, an upper buffer layer, and an upper electrode are stacked on the substrate in the order as listed; an insulating film provided between a plurality of the lower electrodes adjacent to each other; and a light-blocking layer provided in an area overlapping the insulating film in plan view. The lower electrodes of the photodiodes are arranged separated from each other so as to correspond to the photodiodes. The lower buffer layer, the active layer, the upper buffer layer, and the upper electrode are provided continuously across the photodiodes so as to cover the lower electrodes and the insulating film.

### BRIEF DESCRIPTION OF THE DRAWINGS

FIG. 1 is a plan view schematically illustrating a detection device according to a first embodiment of the present disclosure;

FIG. 2 is a block diagram illustrating a configuration example of the detection device according to the first embodiment;

FIG. 3 is a circuit diagram illustrating the detection device according to the first embodiment;

FIG. 4 is an enlarged schematic configuration view of a sensor;

FIG. 5 is a plan view illustrating a light-blocking layer;

FIG. 6 is a sectional view along VI-VI′ of FIG. 5;

FIG. 7 is a sectional view schematically illustrating a detection device according to a second embodiment of the present disclosure; and

FIG. 8 is a sectional view schematically illustrating a detection device according to a third embodiment of the present disclosure.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

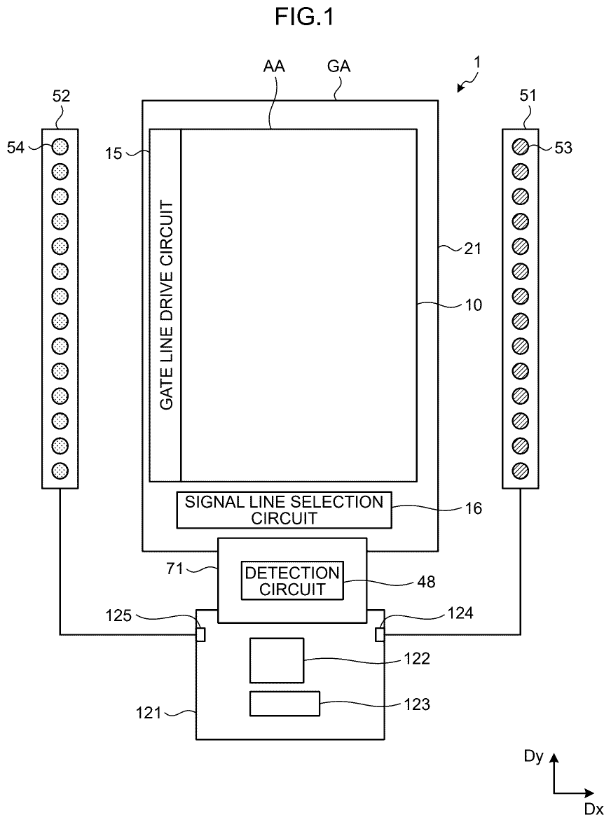

FIG. 1 is a plan view illustrating a detection device according to a first embodiment of the present disclosure. As illustrated in FIG. 1, a detection device 1 includes a sensor base member 21 (substrate), a sensor 10, a gate line drive circuit 15, a signal line selection circuit 16, a detection circuit 48, a control circuit 122, a power supply circuit 123, a first light source base member 51, a second light source base member 52, and light sources 53 and 54. The first light source base member 51 is provided with a plurality of the light sources 53. The second light source base member 52 is provided with a plurality of the light sources 54.

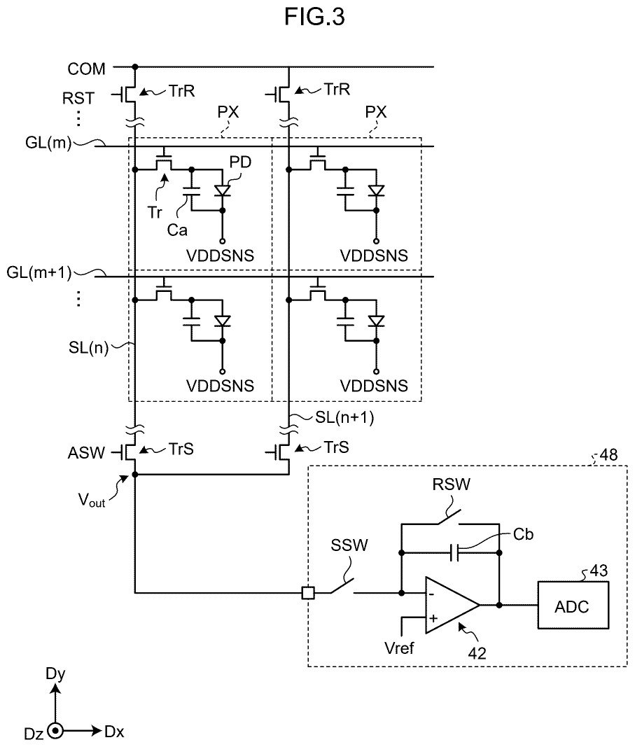

The sensor base member 21 is electrically coupled to a control substrate 121 through a wiring substrate 71. The wiring substrate 71 is, for example, a flexible printed circuit board or a rigid circuit board. The wiring substrate 71 is provided with the detection circuit 48. The control substrate 121 is provided with the control circuit 122 and the power supply circuit 123. The control circuit 122 is a field-programmable gate array (FPGA), for example. The control circuit 122 supplies control signals to the sensor 10, the gate line drive circuit 15, and the signal line selection circuit 16 to control detection operations of the sensor 10. The control circuit 122 supplies control signals to the light sources 53 and 54 to control lighting and non-lighting of the light sources 53 and 54. The power supply circuit 123 supplies voltage signals including, for example, a sensor power supply signal (sensor power supply voltage) VDDSNS (refer to FIG. 3) to the sensor 10, the gate line drive circuit 15, and the signal line selection circuit 16. The power supply circuit 123 supplies a power supply voltage to the light sources 53 and 54.

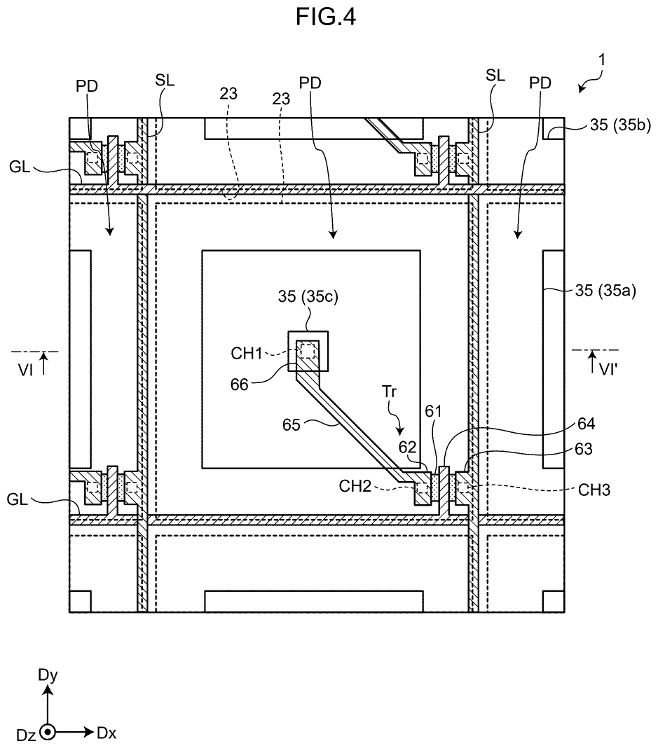

The sensor base member 21 has a detection area AA and a peripheral area GA. The detection area AA is an area provided with a plurality of photodiodes PD (refer to FIG. 4) included in the sensor 10. The peripheral area GA is an area between the outer perimeter of the detection area AA and the outer edges of the sensor base member 21 and is an area not provided with the photodiodes PD.

The gate line drive circuit 15 and the signal line selection circuit 16 are provided in the peripheral area GA. Specifically, the gate line drive circuit 15 is provided in an area extending along a second direction Dy in the peripheral area GA. The signal line selection circuit 16 is provided in an area extending along a first direction Dx in the peripheral area GA, and is provided between the sensor 10 and the detection circuit 48.

In the following description, the first direction Dx is one direction in a plane parallel to the sensor base member 21. The second direction Dy is one direction in the plane parallel to the sensor base member 21 and is a direction orthogonal to the first direction Dx. The second direction Dy may, however, non-orthogonally intersect the first direction Dx. A third direction Dz is a direction orthogonal to the first direction Dx and the second direction Dy and is a direction normal to a principal surface of the sensor base member 21. The term “plan view” refers to a positional relation when viewed from a direction orthogonal to the sensor base member 21.

The light sources 53 are provided on the first light source base member 51, and are arranged along the second direction Dy. The light sources 54 are provided on the second light source base member 52, and are arranged along the second direction Dy. The first light source base member 51 and the second light source base member 52 are electrically coupled to the control circuit 122 and the power supply circuit 123 through respective terminals 124 and 125 provided on the control substrate 121.

For example, inorganic light-emitting diodes (LEDs) or organic electroluminescent (EL) diodes (organic light-emitting diodes (OLEDs)) are used as the light sources 53 and 54. The light sources 53 and 54 emit light having different wavelengths from each other.

First light emitted from the light sources 53 is mainly reflected on a surface of an object to be detected, such as a finger, and enters the sensor 10. As a result, the sensor 10 can detect a fingerprint by detecting a shape of asperities on the surface of the finger or the like. Second light emitted from the light sources 54 is mainly reflected in the finger or the like, or transmitted through the finger or the like, and enters the sensor 10. As a result, the sensor 10 can detect information on a living body in the finger or the like. Examples of the information on the living body include, but are not limited to, pulse waves, pulsation, and a vascular image of the finger or a palm. That is, the detection device 1 may be configured as a fingerprint detection device to detect the fingerprint or a vein detection device to detect a vascular pattern of, for example, veins.

The arrangement of the light sources 53 and 54 illustrated in FIG. 1 is merely an example, and can be changed as appropriate. The detection device 1 is provided with a plurality of types of the light sources 53 and 54 as light sources. However, the light sources are not limited thereto, and may be of one type. For example, the light sources 53 and 54 may be arranged on each of the first and the second light source base members 51 and 52. The light sources 53 and 54 may be provided on one light source base member, or three or more light source base members. Alternatively, only at least one light source needs to be disposed.

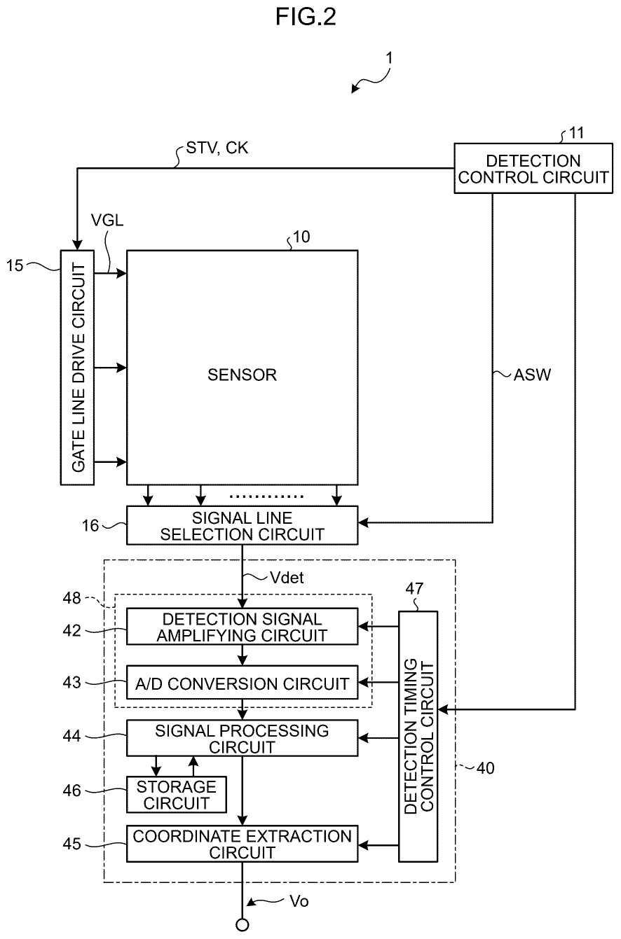

FIG. 2 is a block diagram illustrating a configuration example of the detection device according to the first embodiment. As illustrated in FIG. 2, the detection device 1 further includes a detection control circuit 11 and a detector (detection signal processing circuit) 40. The control circuit 122 includes one, some, or all functions of the detection control circuit 11. The control circuit 122 also includes one, some, or all functions of the detector 40 other than those of the detection circuit 48.

The sensor 10 includes the photodiodes PD. Each of the photodiodes PD included in the sensor 10 outputs an electrical signal corresponding to light received by the photodiode PD as a detection signal Vdet to the signal line selection circuit 16. The sensor 10 performs the detection in response to a gate drive signal VGL supplied from the gate line drive circuit 15.

The detection control circuit 11 supplies respective control signals to the gate line drive circuit 15, the signal line selection circuit 16, and the detector 40 to control operations of these components. The detection control circuit 11 supplies various control signals including, for example, a start signal STV and a clock signal CK to the gate line drive circuit 15. The detection control circuit 11 also supplies various control signals including, for example, a selection signal ASW to the signal line selection circuit 16. The detection control circuit 11 also supplies various control signals to the light sources 53 and 54 to control the lighting and non-lighting of the respective light sources 53 and 54.

The gate line drive circuit 15 drives a plurality of gate lines GL (refer to FIG. 3) based on the various control signals. The gate line drive circuit 15 sequentially or simultaneously selects the gate lines GL, and supplies the gate drive signals VGL to the selected gate lines GL. Through this operation, the gate line drive circuit 15 selects the photodiodes PD coupled to the gate lines GL.

The signal line selection circuit 16 includes a switch circuit that sequentially or simultaneously selects a plurality of signal lines SL (refer to FIG. 3). The signal line selection circuit 16 is a multiplexer, for example. The signal line selection circuit 16 couples the selected signal lines SL to the detection circuit 48 based on the selection signal ASW supplied from the detection control circuit 11. Through this operation, the signal line selection circuit 16 outputs the detection signals Vdet of the photodiodes PD to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 to operate synchronously based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet. The A/D conversion circuit 43 converts analog signals output from the detection signal amplifying circuit 42 into digital signals.

The signal processing circuit 44 detects predetermined physical quantities received by the sensor 10 based on output signals of the detection circuit 48. The signal processing circuit 44 is a logic circuit. The signal processing circuit 44 can detect the asperities on the surface of the finger or the palm based on the signals from the detection circuit 48 when the finger is in contact with or in proximity to a detection surface. The signal processing circuit 44 can detect the information on the living body based on the signals from the detection circuit 48. Examples of the information on the living body include, but are not limited to, the vascular image, the pulse waves, the pulsation, and a blood oxygen level of the finger or the palm.

The storage circuit 46 temporarily stores therein signals calculated by the signal processing circuit 44. The storage circuit 46 may be, for example, a random-access memory (RAM) or a register circuit.

The coordinate extraction circuit 45 obtains detected coordinates of the asperities on the surface of the finger or the like when the contact or proximity of the finger is detected by the signal processing circuit 44. The coordinate extraction circuit 45 also obtains detected coordinates of blood vessels in the finger or the palm. The coordinate extraction circuit 45 is a logic circuit. The coordinate extraction circuit 45 combines the detection signals Vdet output from the photodiodes PD of the sensor 10 to generate two-dimensional information indicating the shape of the asperities on the surface of the finger or the like and two-dimensional information indicating the shape of the blood vessels in the finger or the palm. The coordinate extraction circuit 45 may output the detection signals Vdet as sensor output voltages Vo instead of calculating the detected coordinates.

FIG. 3 is a circuit diagram illustrating the detection device according to the first embodiment. FIG. 3 also illustrates a circuit configuration of the detection circuit 48. As illustrated in FIG. 3, a sensor pixel PX includes the photodiode PD, a capacitive element Ca, and a drive transistor Tr. The capacitive element Ca is capacitance (sensor capacitance) generated in the photodiode PD and is equivalently coupled in parallel to the photodiode PD.

FIG. 3 illustrates two gate lines GL(m) and GL(m+1) arranged in the second direction Dy among the gate lines GL. FIG. 3 also illustrates two signal lines SL(n) and SL(n+1) arranged in the first direction Dx among the signal lines SL. The sensor pixel PX is an area surrounded by the gate lines GL and the signal lines SL.

The drive transistors Tr are provided correspondingly to the photodiodes PD. Each of the drive transistors Tr is configured as a thin-film transistor, and in this example, configured as an n-channel metal oxide semiconductor (MOS) thin-film transistor (TFT).

Each of the gate lines GL is coupled to the gates of the drive transistors Tr arranged in the first direction Dx. Each of the signal lines SL is coupled to either the sources or the drains of the drive transistors Tr arranged in the second direction Dy. The other of the sources and the drains of the drive transistors Tr are coupled to the anodes of the photodiodes PD and the capacitive elements Ca.

The cathode of the photodiode PD is supplied with the sensor power supply signal VDDSNS from the power supply circuit 123 (refer to FIG. 1). The signal line SL and the capacitive element Ca are supplied with a sensor reference voltage COM serving as an initial potential of the signal line SL and the capacitive element Ca from the power supply circuit 123 via a reset transistor TrR.

When the sensor pixel PX is irradiated with light in an exposure period, a current corresponding to the amount of the light flows through the photodiode PD. As a result, an electric charge is stored in the capacitive element Ca. When the drive transistor Tr is turned on in a readout period, a current corresponding to the electric charge stored in the capacitive element Ca flows through the signal line SL. The signal line SL is coupled to the detection circuit 48 through an output transistor TrS of the signal line selection circuit 16. Thus, the detection device 1 can detect a signal corresponding to the amount of the light received by the photodiode PD for each sensor pixel PX.

During the readout period, a switch SSW is turned on to couple the detection circuit 48 to the signal line SL. The detection signal amplifying circuit 42 of the detection circuit 48 converts the current or the electric charge supplied from the signal line SL into a voltage corresponding thereto. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the present embodiment, the same signal as the sensor reference voltage COM is supplied as the reference potential (Vref) voltage. The control circuit 122 (refer to FIG. 1) calculates, as each of the sensor output voltages Vo, the difference between the detection signal Vdet when the photodiode PD is irradiated with light and the detection signal Vdet when the photodiode PD is not irradiated with light. The detection signal amplifying circuit 42 includes a capacitive element Cb and a reset switch RSW. During a reset period, the reset switch RSW is turned on to reset the electric charge of the capacitive element Cb.

The drive transistor Tr is not limited to the n-channel TFT, and may be configured as a p-channel TFT. The pixel circuit of the sensor pixel PX illustrated in FIG. 3 is merely exemplary. The sensor pixel PX may be provided with a plurality of transistors corresponding to each of the photodiodes PD.

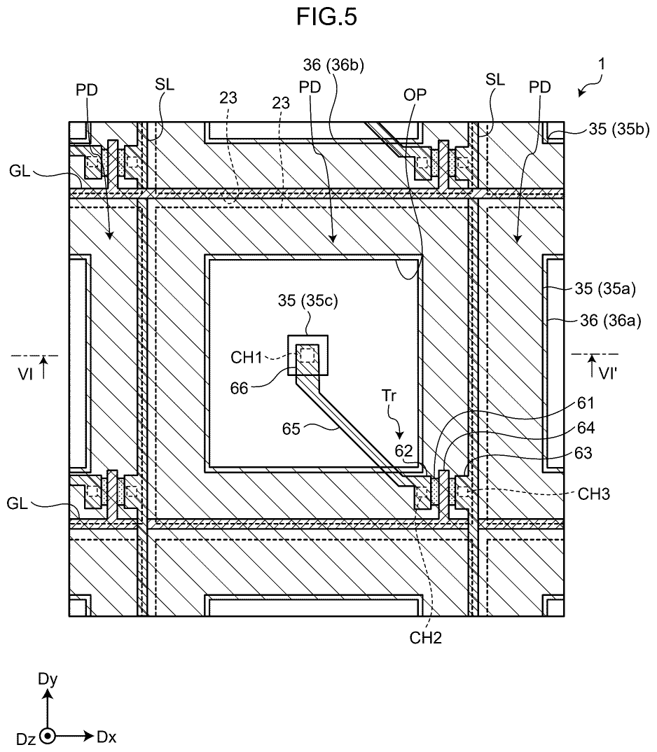

The following describes a configuration of the photodiode PD. FIG. 4 is an enlarged schematic configuration view of the sensor. FIG. 5 is a plan view illustrating a light-blocking layer. FIG. 4 is a plan view illustrating a portion of the sensor 10, and is a plan view excluding a light-blocking layer 36 from FIG. 5. In FIG. 5, the light-blocking layer 36 is illustrated in a hatched manner

As illustrated in FIGS. 4 and 5, the detection device 1 includes the photodiodes PD provided on the sensor base member 21, an insulating film 35, and the light-blocking layer 36. The gate lines GL each extend in the first direction Dx, and are arranged with gaps interposed therebetween in the second direction Dy. The signal lines SL each extend in the second direction Dy and are arranged with gaps interposed therebetween in the first direction Dx. The photodiodes PD are each provided in an area surrounded by two of the gate lines GL and two of the signal lines SL and are provided in a matrix having a row-column configuration on the sensor base member 21.

Lower electrodes 23 of the photodiodes PD are provided in a matrix having a row-column configuration on the sensor base member 21 so as to correspond to the respective photodiodes PD. In the example illustrated in FIG. 4, the right and bottom sides of each of the lower electrodes 23 are provided so as to overlap part of the signal line SL and part of the gate line GL, respectively. The left and top sides of the lower electrode 23 are located so as to be spaced from the signal line SL and the gate line GL, respectively. This configuration can increase the area of the lower electrode 23 in the area surrounded by two of the gate lines GL and two of the signal lines SL, and thus can improve the detection sensitivity of the photodiode PD.

The drive transistor Tr is provided in an area overlapping the lower electrode 23 of the photodiode PD. Specifically, the drive transistor Tr includes a semiconductor layer 61, a source electrode 62, a drain electrode 63, and a gate electrode 64. The semiconductor layer 61 extends along the gate line GL and is provided so as to intersect the gate electrode 64 in plan view. The gate electrode 64 is coupled to the gate line GL and extends in a direction (second direction Dy) orthogonal to the gate line GL.

One end side of the semiconductor layer 61 is coupled to the source electrode 62 through a contact hole CH2. The source electrode 62 is coupled to coupling wiring 65 and a coupling pad 66 and extended to a central portion of the photodiode PD (lower electrode 23). The lower electrode 23 is coupled to the coupling pad 66 through a contact hole CH1 at the central portion. Such a configuration electrically couples the source electrode 62 of the drive transistor Tr to the photodiode PD. The other end side of the semiconductor layer 61 is coupled to the drain electrode 63 through a contact hole CH3. The drain electrode 63 is coupled to the signal line SL.

The insulating film 35 is provided between the lower electrodes 23 adjacent in the first direction Dx and the second direction Dy, and is provided so as to cover the peripheries of the lower electrodes 23. In more detail, the insulating film 35 is formed in a grid pattern with first extending portions 35a and second extending portions 35b intersecting each other. Each of the first extending portions 35a extends in the second direction Dy. The first extending portion 35a is provided so as to overlap the signal line SL and extends along the signal line SL. Each of the second extending portions 35b extends in the first direction Dx. The second extending portion 35b is provided so as to overlap the gate line GL and extends along the gate line GL.

In other words, openings are formed in areas of the insulating film 35 overlapping the respective lower electrodes 23. The opening is an area surrounded by two of the first extending portions 35a and two of the second extending portions 35b. An island 35c is provided so as to be separated from the first extending portions 35a and the second extending portions 35b and is provided in an area overlapping the contact hole CH1 in the central portion of the photodiode PD (lower electrode 23).

As illustrated in FIG. 5, the light-blocking layer 36 is provided in an area overlapping the insulating film 35 in plan view. The light-blocking layer 36 is formed of a non-light-transmitting material. The light-blocking layer 36 is provided in an area between the lower electrodes 23 adjacent in the first direction Dx, an area between the lower electrodes 23 adjacent in the second direction Dy, and areas overlapping the peripheries of the lower electrodes 23.

In more detail, the light-blocking layer 36 includes a first light-blocker 36a and a second light-blocker 36b. The light-blocking layer 36 is formed in a grid pattern with the first light-blockers 36a intersecting the second light-blockers 36b. Each of the first light-blockers 36a extends in the second direction Dy. The first light-blocker 36a overlaps the first extending portion 35a of the insulating film 35 and extends along the first extending portion 35a of the insulating film 35. Each of the second light-blockers 36b extends in the first direction Dx. The second light-blocker 36b overlaps the second extending portion 35b of the insulating film 35 and extends along the second extending portion 35b of the insulating film 35.

An opening OP is formed in an area of the light-blocking layer 36 overlapping the opening in the insulating film 35. The opening OP in the light-blocking layer 36 is an area surrounded by two of the first light-blockers 36a and two of the second light-blockers 36b.

The shapes, the arrangement pitch, and the like of the lower electrode 23, the insulating film 35, and the light-blocking layer 36 illustrated in FIGS. 4 and 5 are only exemplary and can be changed as appropriate according to the characteristics and the detection accuracy required for the detection device 1.

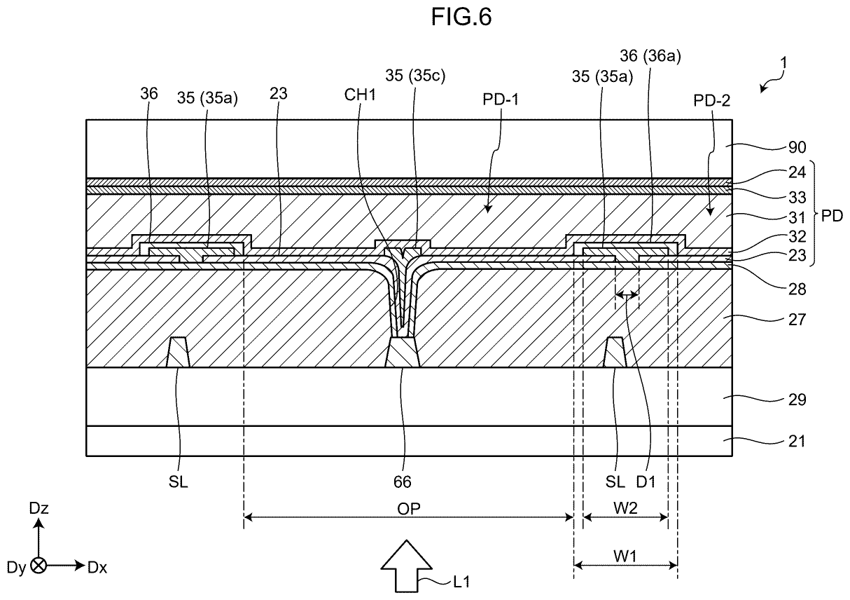

FIG. 6 is a sectional view along VI-VI′ of FIG. 5. As illustrated in FIG. 6, in the detection device 1, a circuit forming layer 29, an insulating film 27 (organic insulating film), an insulating film 28 (inorganic insulating film), the photodiode PD, and a sealing film 90 are stacked in this order on the sensor base member 21. The sensor base member 21 is an insulating substrate and is made using, for example, a glass substrate of quartz, alkali-free glass, or the like. The sensor base member 21 is not limited to having a flat plate shape, but may have a curved surface. In this case, the sensor base member 21 may be made of a film-like resinous material.

The circuit forming layer 29 is a layer that is provided on the sensor base member 21. The circuit forming layer 29 is provided with various transistors, such as the drive transistors Tr illustrated in FIGS. 3 and 4, and various types of wiring, such as the gate lines GL and the signal lines SL. Specifically, the circuit forming layer 29 includes the drive transistors Tr, at least part of the gate lines GL, and at least part of the signal lines SL. FIG. 6 illustrates the signal lines SL on the circuit forming layer 29 that are coupled to the drive transistors Tr. The insulating film 27 is provided on the circuit forming layer 29 including the drive transistors Tr so as to cover the signal lines SL. The insulating film 27 is an organic planarizing film formed of an organic insulating material.

The insulating film 28 is provided on the insulating film 27. The insulating film 28 is a barrier film formed of an inorganic insulating material, such as a silicon nitride (SiN) film.

The photodiode PD, the insulating film 35, and the light-blocking layer 36 are provided on the insulating film 28. In more detail, the photodiode PD includes the lower electrode 23, a lower buffer layer 32, an active layer 31, an upper buffer layer 33, and an upper electrode 24. In the photodiode PD, the lower electrode 23, the lower buffer layer 32, the active layer 31, the upper buffer layer 33, and the upper electrode 24 are stacked in this order in a direction orthogonal to the sensor base member 21. The photodiode PD of the present embodiment is an organic photodiode (OPD) made using an organic semiconductor as the active layer 31.

The lower electrode 23 is an anode electrode of the photodiode PD, and is formed of, for example, a light-transmitting conductive material such as indium tin oxide (ITO). The lower electrodes 23 are separated from each other so as to correspond to the photodiodes PD. The lower buffer layer 32, the active layer 31, the upper buffer layer 33, and the upper electrode 24 are provided continuously across the photodiodes PD. Specifically, the lower buffer layer 32, the active layer 31, the upper buffer layer 33, and the upper electrode 24 are provided so as to overlap an adjacent pair of the lower electrode 23 of a photodiode PD-1 and the lower electrode 23 of a photodiode PD-2, and overlap also the insulating film 35 and the light-blocking layer 36 between the photodiodes PD-1 and PD-2.

The insulating film 35 (first extending portion 35a) is provided on the insulating film 28 between the adjacent lower electrodes 23, and covers the peripheries of the lower electrodes 23. In the present embodiment, the insulating film 35 is formed of an inorganic insulating material, such as a silicon nitride (SiN) film or a silicon oxide (SiO₂) film. The insulating film 35 (first extending portion 35a) insulates the lower electrodes 23 of the adjacent photodiodes PD from each other.

The light-blocking layer 36 (first light-blocker 36a) is provided so as to cover the insulating film 35. In more detail, the light-blocking layer 36 is provided so as to cover the upper surface and the side surfaces of the insulating film 35. The light-blocking layer 36 is also provided in the area between the adjacent lower electrodes 23 and in the area overlapping the peripheries of the lower electrodes 23.

A width W1 of the light-blocking layer 36 is equal to or larger than a distance D1 between the adjacent lower electrodes 23. The width W1 of the light-blocking layer 36 is larger than a width W2 of the insulating film 35 provided in an area overlapping the light-blocking layer 36. One end side and the other end side in the width direction of the light-blocking layer 36 are in contact with the respective adjacent lower electrodes 23. In the present embodiment, the light-blocking layer 36 is formed of a non-light-transmitting insulating material such as a resinous material. This material ensures insulation between the adjacent lower electrodes 23 even through the width W1 of the light-blocking layer 36 is formed larger than the width W2 of the insulating film 35.

The contact hole CH1 is provided so as to penetrate the insulating film 27 in the thickness direction thereof (third direction Dz) at the central portion of the lower electrode 23. The lower electrode 23 is coupled to the coupling pad 66 at the bottom of the contact hole CH1. The island 35c is provided so as to cover the contact hole CH1 and covers the lower electrode 23 in the contact hole CH1. The island 35c overlaps the coupling pad 66 in plan view. The lower electrode 23 is provided so as to cover the bottom of the contact hole CH1 and is conductive to the coupling pad 66 at the bottom of the contact hole CH1.

The active layer 31 changes in characteristics (for example, voltage-current characteristics and resistance value) according to light emitted thereto. An organic material is used as a material of the active layer 31. Specifically, the active layer 31 has a bulk heterostructure containing a mixture of a p-channel organic semiconductor and an n-channel fullerene derivative ((6,6)-phenyl-C61-butyric acid methyl ester (PCBM)) that is an n-channel organic semiconductor. As the active layer 31, low-molecular-weight organic materials can be used including, for example, fullerene (C₆₀), phenyl-C₆₁-butyric acid methyl ester ((6,6)-phenyl-C61-butyric acid methyl ester (PCBM)), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using any of the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 and the upper buffer layer 33 are provided to facilitate holes and electrons generated in the active layer 31 to reach the lower electrode 23 or the upper electrode 24. The lower buffer layer 32 is in direct contact with the top of the lower electrode 23 and is provided so as to cover the insulating film 35 and the light-blocking layer 36 between the adjacent lower electrodes 23. That is, the light-blocking layer 36 is provided between the insulating film 35 and the lower buffer layer 32 in the third direction Dz.

If the detection device 1 is a bottom-illuminated optical sensor, the lower buffer layer 32 is an electron transport layer and the upper buffer layer 33 is a hole transport layer. If the detection device 1 is a top-illuminated optical sensor, the lower buffer layer 32 is a hole transport layer and the upper buffer layer 33 is an electron transport layer. The active layer 31 is in direct contact with the top of the lower buffer layer 32. The material of the hole transport layer is a metal oxide layer. For example, tungsten oxide (WO₃) or molybdenum oxide is used as the oxide metal layer.

The upper buffer layer 33 is in direct contact with the top of the active layer 31, and the upper electrode 24 is in direct contact with the top of the upper buffer layer 33. Polyethylenimine ethoxylated (PEIE) is used as a material of the electron transport layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film, but may be formed as a multilayered film that includes an electron block layer and a hole block layer.

The upper electrode 24 is provided on the upper buffer layer 33. The upper electrode 24 is a cathode electrode of the photodiode PD and is continuously formed across the entire detection area AA. In other words, the upper electrode 24 is continuously provided at the top of the photodiodes PD. The upper electrode 24 faces the lower electrodes 23 with the lower buffer layer 32, the active layer 31, and the upper buffer layer 33 interposed therebetween. The upper electrode 24 is formed, for example, of a light-transmitting conductive material such as ITO or indium zinc oxide (IZO). The upper electrode 24 may be a multilayered film of a plurality of light-transmitting conductive materials.

The sealing film 90 is provided on the upper electrode 24. An inorganic film, such as a silicon nitride film, or an aluminum oxide film or a resin film, such as an acrylic film, is used as the sealing film 90. The sealing film 90 is not limited to a single layer and may be a multilayered film having two or more layers obtained by combining the inorganic film with the resin film mentioned above. The sealing film 90 well seals the photodiode PD, and thus can reduce moisture entering the photodiode PD from the upper surface side thereof.

The detection device 1 of the present embodiment is configured as the bottom-illuminated optical sensor. That is, light L1 is emitted from the light sources 53 and 54 (refer to FIG. 1) to the object to be detected such as the finger. The light L1 transmitted through or reflected by the object to be detected passes through the sensor base member 21 and reaches the lower electrode 23 of the photodiode PD. The light L1 is applied to the active layer 31 of the photodiode PD through the opening OP in the light-blocking layer 36. Carriers (holes and electrons) generated in the active layer 31 reach the lower electrode 23 and the upper electrode 24 through the lower buffer layer 32 and the upper buffer layer 33, respectively.

The light L1 is blocked in the area overlapping the light-blocking layer 36 and is not applied to the active layer 31 located in the area overlapping the light-blocking layer 36. In more detail, the lower buffer layer 32, the active layer 31, the upper buffer layer 33, and the upper electrode 24 are not irradiated with the light L1 in portions overlapping the insulating film 35 and portions overlapping the area between the adjacent lower electrodes 23. This configuration reduces generation of the carriers (holes and electrons) in the portion of the active layer 31 that overlaps the light-blocking layer 36.

If the light-blocking layer 36 is not provided, carriers generated in the active layer 31 in the area overlapping the insulating film 35 may have a delayed response until reaching the lower electrode 23, compared with carriers generated in the active layer 31 in an area not overlapping the insulating film 35. In more detail, in a portion of the photodiode PD overlapping the insulating film 35, the insulating film 35 is provided between the lower electrode 23 and the lower buffer layer 32. Therefore, the carriers generated in the active layer 31 in the area overlapping the insulating film 35 do not reach the lower electrode 23 directly below the insulating film 35, and reach the lower electrode 23 in the area not overlapping the insulating film 35 through the lower buffer layer 32. Carriers generated in the active layer 31 in the area between the adjacent lower electrodes 23 reach the lower electrode 23 in the area not overlapping the insulating film 35 through the lower buffer layer 32.

Thus, if the light-blocking layer 36 is not provided, a delay in optical responsivity may occur in the active layer 31 in the area overlapping the insulating film 35. The distance between the adjacent lower electrodes 23 and the overlap area between the lower electrode 23 and the insulating film 35 may cause differences in dependency of the optical responsivity.

In the present embodiment, as described above, the light-blocking layer 36 is provided in the area overlapping the insulating film 35, the generation of the carriers (holes and electrons) is reduced in the portion of the active layer 31 overlapping the light-blocking layer 36 (that is, in the portion overlapping the insulating film 35 and the portion overlapping the area between the adjacent lower electrodes 23). Therefore, a delay in arrival time of the carriers (holes and electrons) generated in the active layer 31 can be reduced between a portion of the photodiode PD overlapping the insulating film 35 and a portion of the photodiode PD not overlapping the insulating film 35. As a result, the detection device 1 having the OPD can improve the detection accuracy.

In the present embodiment, the insulating film 35 is provided between the adjacent lower electrodes 23. Therefore, a portion of the lower buffer layer 32 that overlaps the insulating film 35 is thinner than a portion thereof that does not overlap the insulating film 35 but overlaps the lower electrode 23. Therefore, the portion of the lower buffer layer 32 overlapping the insulating film 35 has a higher resistance value than the portion thereof overlapping the lower electrode 23 and serves as a potential barrier between adjacent lower electrodes 23. Therefore, in the present embodiment, leakage currents flowing between the adjacent lower electrodes 23 can be reduced compared with a case where the lower buffer layer 32 is continuously provided having a constant thickness over the adjacent photodiodes PD.

The configuration of the photodiode PD illustrated in FIGS. 4 to 6 is merely exemplary and can be changed as appropriate. For example, the upper electrode 24 may be the anode electrode of the photodiode PD, and the lower electrode 23 may be the cathode electrode of the photodiode PD.

### Second Embodiment

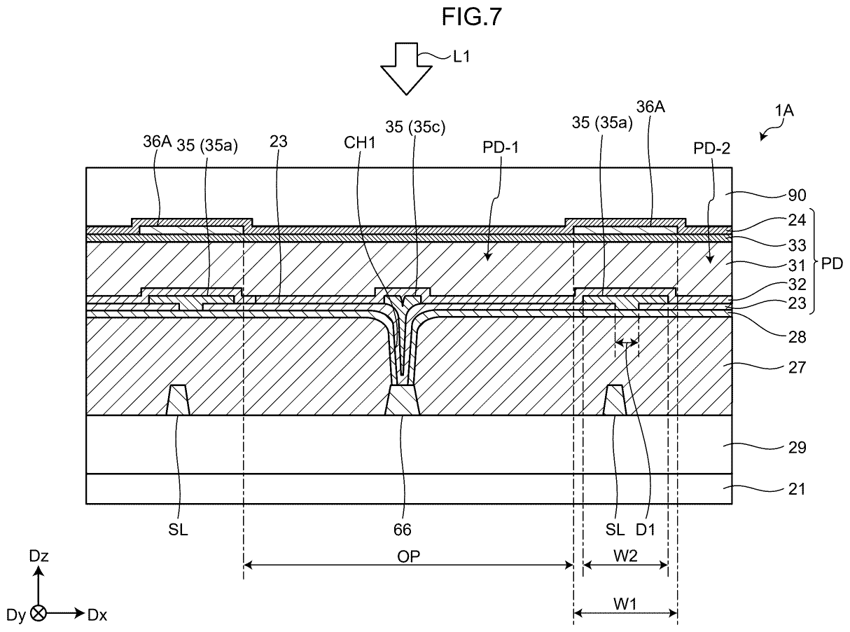

FIG. 7 is a sectional view schematically illustrating a detection device according to a second embodiment of the present disclosure. In the following description, the same components as those described in the embodiment above are denoted by the same reference numerals, and the description thereof will not be repeated.

As illustrated in FIG. 7, in a detection device 1A according to the second embodiment, a light-blocking layer 36A is provided between the upper buffer layer 33 and the upper electrode 24 in the third direction Dz. The configuration in plan view is the same as in the first embodiment illustrated in FIG. 5, and the light-blocking layer 36A is provided in the area overlapping the insulating film 35. As illustrated in FIG. 7, the light-blocking layer 36A is provided in the same layer as the upper electrode 24 on the upper buffer layer 33. The upper electrode 24 is provided on the upper buffer layer 33 so as to cover the light-blocking layer 36A. In the present embodiment, the light-blocking layer 36A is formed of a non-light-transmitting metal layer or alloy layer. The light-blocking layer 36A is in contact with the upper electrode 24 and has the same potential as the upper electrode 24.

The detection device 1A of the present embodiment is configured as a top-illuminated optical sensor. That is, the light L1 emitted from the light sources 53 and 54 (refer to FIG. 1) and transmitted through or reflected by the object to be detected, is applied to the upper electrode 24 of the photodiode PD through the sealing film 90. The light L1 is applied to the active layer 31 of the photodiode PD through the opening OP in the light-blocking layer 36A. The carriers (holes and electrons) generated in the active layer 31 reach the lower electrode 23 and the upper electrode 24 through the lower buffer layer 32 and the upper buffer layer 33, respectively.

In the present embodiment, the light L1 is also blocked in an area overlapping the light-blocking layer 36A, and is not emitted to an area of the active layer 31 overlapping the light-blocking layer 36A. This configuration reduces the generation of the carriers (holes and electrons) in the portion of the active layer 31 that overlaps the light-blocking layer 36A (a portion overlapping the insulating film 35 and a portion overlapping the area between the adjacent lower electrodes 23). As a result, the detection device 1 having the OPD can improve the detection accuracy.

### Third Embodiment

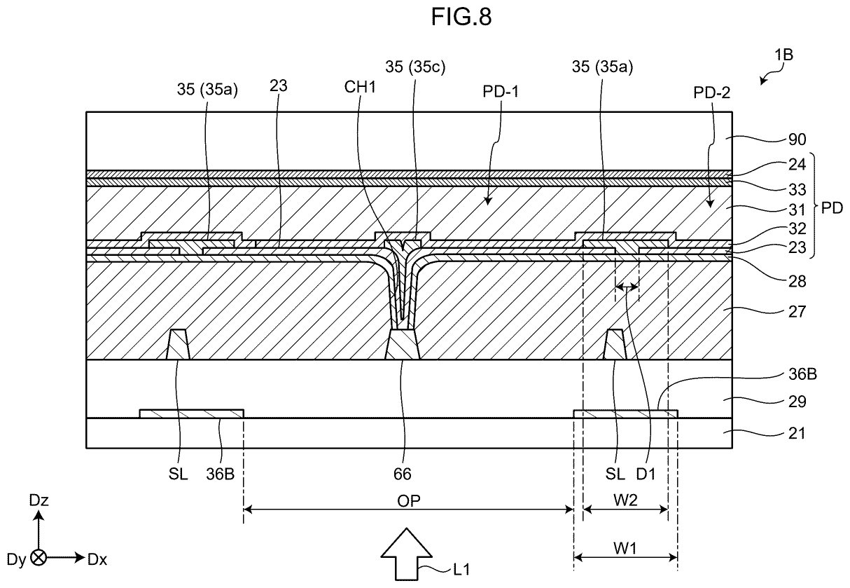

FIG. 8 is a sectional view schematically illustrating a detection device according to a third embodiment of the present disclosure. As illustrated in FIG. 8, in a detection device 1B according to the third embodiment, a light-blocking layer 36B is provided between the sensor base member 21 and the insulating film 27 (organic insulating film) in the third direction Dz. Specifically, the light-blocking layer 36B is provided between the sensor base member 21 and the circuit forming layer 29.

The light-blocking layer 36B is formed of the same metal material or alloy material as the gate line GL or the signal line SL (refer to FIG. 4) provided on the circuit forming layer 29. For example, aluminum (Al) or molybdenum-tungsten (MoW) is used as the light-blocking layer 36B.

The detection device 1B of the present embodiment is configured as a bottom-illuminated optical sensor. That is, the light L1 emitted from the light sources 53 and 54 (refer to FIG. 1) and transmitted through or reflected by the object to be detected, is applied to the lower electrode 23 of the photodiode PD through the sensor base member 21. The light L1 is applied to the active layer 31 of the photodiode PD through the opening OP in the light-blocking layer 36B. The carriers (holes and electrons) generated in the active layer 31 reach the lower electrode 23 and the upper electrode 24 through the lower buffer layer 32 and the upper buffer layer 33, respectively.

Also, in the present embodiment, the light L1 is blocked in an area overlapping the light-blocking layer 36B and is not applied to the active layer 31 located in the area overlapping the light-blocking layer 36B. As a result, the generation of the carriers (holes and electrons) is reduced in a portion of the active layer 31 overlapping the light-blocking layer 36B (portion overlapping the insulating film 35). As a result, the detection device 1 having the OPD can improve the detection accuracy.

In the example illustrated in FIG. 8, the light-blocking layer 36B is provided between the sensor base member 21 and the circuit forming layer 29, but is not limited to this location. The light-blocking layer 36B only needs to be provided between the sensor base member 21 and the insulating film 27 in the third direction Dz and may be provided, for example, in the circuit forming layer 29, or between the insulating film 27 and the circuit forming layer 29. At least two of the first to the third embodiments described above may be combined.

While the preferred embodiments of the present disclosure have been described above, the present disclosure is not limited to the embodiments described above. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modifications described above.

What is claimed is:

1. A detection device comprising:
a substrate;
a plurality of photodiodes in each of which a lower electrode, a lower buffer layer, an active layer, an upper buffer layer, and an upper electrode are stacked on the substrate in the order as listed;
an insulating film provided between a plurality of the lower electrodes adjacent to each other; and
a light-blocking layer provided in an area overlapping the insulating film in plan view, wherein
the lower electrodes of the photodiodes are arranged separated from each other so as to correspond to the photodiodes, and
the lower buffer layer, the active layer, the upper buffer layer, and the upper electrode are provided continuously across the photodiodes so as to cover the lower electrodes and the insulating film.

2. The detection device according to claim 1, wherein the light-blocking layer is provided between the insulating film and the upper buffer layer in a direction orthogonal to the substrate.

3. The detection device according to claim 1, wherein a width of the light-blocking layer is equal to or larger than a distance between the adjacent lower electrodes.

4. The detection device according to claim 1, wherein the light-blocking layer is provided so as to cover an upper surface and side surfaces of the insulating film.

5. The detection device according to claim 1, wherein the light-blocking layer is provided between the upper buffer layer and the upper electrode in a direction orthogonal to the substrate.

6. The detection device according to claim 1, wherein the light-blocking layer is a metal layer or an alloy layer provided in the same layer as the upper electrode.

7. The detection device according to claim 5, comprising a light source configured to emit light to an object to be detected, wherein
the light emitted from the light source and transmitted through or reflected by the object to be detected is applied to the upper electrode of the photodiodes.

8. The detection device according to claim 1, comprising a circuit forming layer, an organic insulating film, and an inorganic insulating film that are stacked on the substrate in the order as listed, wherein
the photodiodes are provided on the inorganic insulating film, and
the light-blocking layer is provided between the substrate and the organic insulating film in a direction orthogonal to the substrate.

9. The detection device according to claim 8, wherein
the circuit forming layer includes drive transistors to drive the photodiodes, and at least part of gate lines and at least part of signal lines, the gate lines and the signal lines being coupled to the drive transistors, and
the light-blocking layer is formed of the same metal material or alloy material as the gate lines or the signal lines.

10. The detection device according to claim 1, wherein a width of the light-blocking layer is longer than a width of the insulating film.

11. The detection device according to claim 2, comprising a light source configured to emit light to an object to be detected, wherein
the light emitted from the light source and transmitted through or reflected by the object to be detected is applied to the lower electrodes of the photodiodes.

12. The detection device according to claim 8, comprising a light source configured to emit light to an object to be detected, wherein
the light emitted from the light source and transmitted through or reflected by the object to be detected is applied to the lower electrodes of the photodiodes.

13. The detection device according to claim 1, wherein the photodiodes are organic photodiodes (OPDs).
